(19) United States
(12) Patent Application Publication
(10) Pub. No.: US 2024/0421276 A1
(43) Pub. Date: Dec. 19, 2024

(54) Display Device

(71) Applicant: LG Display Co., Ltd., Seoul (KR)

(72) Inventors: Soyi Lee, Paju-si (KR); JongSung Kim, Seoul (KR); JongBeom Lee, Paju-si (KR)

(21) Appl. No.: 18/740,490

(22) Filed: Jun. 11, 2024

(30) Foreign Application Priority Data
Jun. 15, 2023 (KR) 10-2023-0076782

(51) Int. Cl. H01L 33/62; H01L 25/075; H01L 25/16; H01L 33/10

(52) U.S. Cl. CPC H01L 33/62; H01L 25/0753; H01L 25/167; H01L 33/10

(57) ABSTRACT

A display device includes a substrate which includes a plurality of sub pixels including a first sub pixel, a second sub pixel, and a sharing sub pixel disposed between the first sub pixel and the second sub pixel, a plurality of transistors which is disposed in the first sub pixel and the second sub pixel, among the plurality of sub pixels, a common power line which is disposed at one sides of the first sub pixel, the second sub pixel, and the sharing sub pixel to apply a common power to the first sub pixel, the second sub pixel, and the sharing sub pixel and a plurality of connection patterns which is connected to the plurality of transistors, respectively, to be disposed at the other sides of the first sub pixel and the second sub pixel, and is spaced apart from each other.

### CROSS-REFERENCE TO RELATED APPLICATIONS

This application claims the priority of Republic of Korea Patent Application No. 10-2023-0076782 filed on Jun. 15, 2023, in the Korean Intellectual Property Office, the disclosure of which is incorporated herein by reference.

### BACKGROUND

### Field

The present disclosure relates to a display device, and more particularly, to a display device using a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to reduce the number of light emitting diodes required for repair by allowing two adjacent sub pixels to share one auxiliary sub pixel.

Another object to be achieved by the present disclosure is to provide a display device with a reduced manufacturing cost and an improved manufacturing yield.

Still another object to be achieved by the present disclosure is to provide a display device which drives an auxiliary sub pixel in a predetermined position without separate position programming.

Still another object to be achieved by the present disclosure is to provide a display device which drives an auxiliary sub pixel using a pixel circuit of an adjacent sub pixel without placing a separate pixel circuit in the auxiliary sub pixel to ensure a sufficient design area.

Objects of the present disclosure are not limited to the above-mentioned objects, and other objects, which are not mentioned above, can be clearly understood by those skilled in the art from the following descriptions.

According to an aspect of the present disclosure, a display device includes a substrate which includes a plurality of sub pixels including a first sub pixel, a second sub pixel, and a sharing sub pixel disposed between the first sub pixel and the second sub pixel, a plurality of transistors which is disposed in the first sub pixel and the second sub pixel, among the plurality of sub pixels, a common power line which is disposed at one sides of the first sub pixel, the second sub pixel, and the sharing sub pixel to apply a common power to the first sub pixel, the second sub pixel, and the sharing sub pixel, and a plurality of connection patterns which is connected to the plurality of transistors, respectively, to be disposed at the other sides of the first sub pixel and the second sub pixel, and is spaced apart from each other. Accordingly, two sub pixels share one auxiliary sub pixel to ensure a design area and implement a high resolution.

Other detailed matters of the exemplary embodiments are included in the detailed description and the drawings.

According to the present disclosure, the number of light emitting diodes for repair is reduced by sharing an auxiliary sub pixel to reduce a manufacturing cost and improve a manufacturing yield.

According to the present disclosure, a separate pixel circuit is not disposed in the auxiliary sub pixel to ensure a sufficient design area and implement a high resolution.

According to the present disclosure, the auxiliary sub pixel is driven in a predetermined position without separate position programming.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings.

FIG. 1 is a schematic diagram of a display device according to an exemplary embodiment of the present disclosure.

FIG. 2A is a plan view of a pixel area of a display device according to an exemplary embodiment of the present disclosure.

FIG. 2B is a cross-sectional view taken along the line IIb-IIb′ of FIG. 2A according to an embodiment of the present disclosure.

FIG. 3A is a plan view of a pixel area of a display device according to another exemplary embodiment of the present disclosure.

FIG. 3B is a cross-sectional view taken along the line IIIb-IIIb′ of FIG. 3A according to an embodiment of the present disclosure.

FIG. 4A is a plan view of a pixel area of a display device according to still another exemplary embodiment of the present disclosure.

FIG. 4B is a cross-sectional view taken along the line IVb-IVb′ of FIG. 4A according to an embodiment of the present disclosure.

FIG. 5A is a plan view of a pixel area of a display device according to still another exemplary embodiment of the present disclosure.

FIG. 5B is a cross-sectional view taken along the line Vb-Vb′ of FIG. 5A according to an embodiment of the present disclosure.

FIG. 6A is a plan view of a pixel area of a display device according to still another exemplary embodiment of the present disclosure.

FIG. 6B is a cross-sectional view taken along the line VIb-VIb′ of FIG. 6A according to an embodiment of the present disclosure.

FIG. 7A is a plan view of a pixel area of a display device according to still another exemplary embodiment of the present disclosure.

FIG. 7B is a cross-sectional view taken along the line VIIb-VIIb′ of FIG. 7A according to an embodiment of the present disclosure.

FIG. 8A is a plan view of a pixel area of a display device according to still another exemplary embodiment of the present disclosure.

FIG. 8B is a cross-sectional view taken along the line VIIIb-VIIIb′ of FIG. 8A according to an embodiment of the present disclosure.

FIGS. 9A to 9C are schematic process diagrams for explaining a manufacturing method of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto.

Like reference numerals generally denote like elements throughout the specification. Further, following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

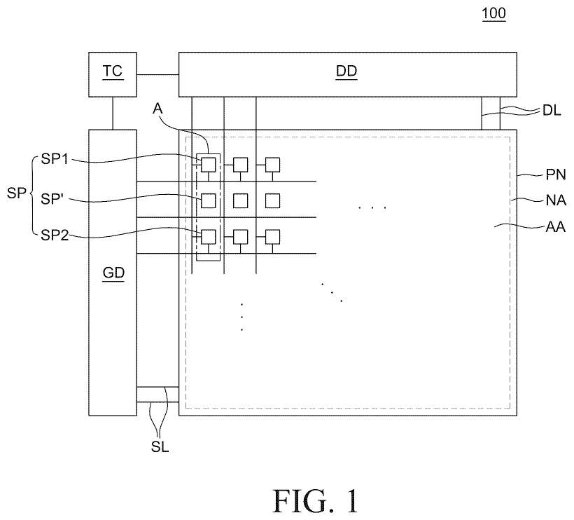

FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. The plurality of sub pixels SP may include a first sub pixel SP1, a second sub pixel SP2, and a sharing sub pixel SP′. The sharing sub pixel SP′ may be disposed between the first sub pixel SP1 and the second sub pixel SP2. At this time, the first sub pixel SP1, the second sub pixel SP2, and the sharing sub pixel SP′ may emit light with the same color. That is, all the first sub pixel SP1, the second sub pixel SP2, and the sharing sub pixel SP′ may be sub pixels for emitting red light, or sub pixels for emitting green light, or sub pixels for emitting blue light.

In the display panel PN, the plurality of scan lines SL and the plurality of data lines DL intersect each other and each of the first sub pixel SP1, the second sub pixel SP2, and the sharing sub pixel SP′, among the plurality of sub pixels SP, is connected to the scan lines SL and the data lines DL. The sharing sub pixel SP′ may not be connected to the scan lines SL and the data lines DL. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel. In each of the plurality of sub pixels SP, a light emitting diode, and a transistor for driving the light emitting diode are disposed, but in the sharing sub pixel SP′, a transistor for driving the light emitting diode LED disposed in the sharing sub pixel SP′ may not be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of wiring lines which transmits various signals to the plurality of sub pixels SP is disposed. For example, the plurality of wiring lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, a driving IC, such as a gate driver IC or a data driver IC, or the like, may be disposed.

In the meantime, the non-active area NA may be located on a rear surface of the display panel PN, that is, a surface on which the sub pixels SP are not disposed or may be omitted and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board PCB. The data driver DD and the timing controller TC may be electrically connected to the display panel PN by bonding the flexible film and the printed circuit board PCB to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA may be reduced or minimized on the front surface of the display panel PN. That is, when the gate driver GD, the data driver DD, and the timing controller TC are connected to the display panel PN as described above, a zero bezel with substantially no bezel may be implemented.

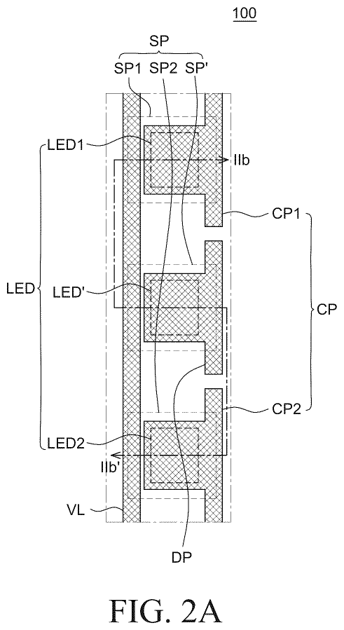

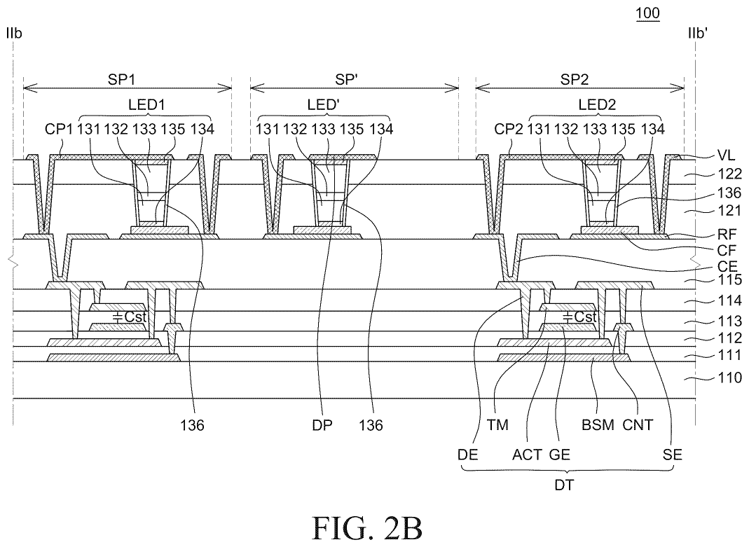

FIG. 2A is a plan view of a pixel area of a display device according to an exemplary embodiment of the present disclosure and FIG. 2B is a cross-sectional view of a pixel area of a display device according to an exemplary embodiment of the present disclosure. In FIGS. 2A and 2B, it is illustrated that all the light emitting diodes disposed in the first sub pixel SP1, the second sub pixel SP2, and the sharing sub pixel SP′ are normal and the light emitting diodes are normally transferred. In FIG. 2A, for the convenience of description, among various components of the display device 100, only a light emitting diode LED, a common power line VL, a connection pattern CP, and a dummy pattern DP are illustrated.

Referring to FIG. 2A, the plurality of sub pixels SP may include a first sub pixel SP1, a second sub pixel SP2, and a sharing sub pixel SP′. The first sub pixel SP1 and the second sub pixel SP2 are sub pixels which are generally used and the sharing sub pixel SP′ is a sub pixel which is used when any one of the first sub pixel SP1 and the second sub pixel SP2 is defective. For example, when a light emitting diode LED itself disposed in any one of the first sub pixel SP1 and the second sub pixel SP2 is defective, or the light emitting diode LED is not transferred, or the light emitting diode LED is erroneously transferred to be deviated from a normal position, the sharing sub pixel SP′ may be used, rather than the corresponding sub pixel. Hereinafter, as described above, an example that a sharing light emitting diode LED′ of the first sub pixel SP1, the second sub pixel SP2, and the sharing sub pixel SP′ is normal and is normally transferred will be described.

Referring to FIGS. 2A and 2B together, the substrate 110 is a substrate which supports components disposed above the display device 100 and may be an insulating substrate. For example, the substrate 110 may be formed of glass or resin. Further, the substrate 110 may include polymer or plastic. In some exemplary embodiments, the substrate 110 may be formed of a plastic material having flexibility. A plurality of pixels is formed on the substrate 110 to display images.

A pixel circuit for driving the light emitting diode is disposed in each of the first sub pixel SP1 and the second sub pixel SP2, among the plurality of sub pixels SP on the substrate 110. That is, the pixel circuit is not disposed in the sharing sub pixel SP′.

The pixel circuit may include a plurality of transistors and a plurality of capacitors. In FIG. 2B, for the convenience of description, only a driving transistor DT and a storage capacitor Cst, among configurations of the pixel circuit are illustrated. However, the pixel circuit may further include a switching transistor, a sensing transistor, an emission control transistor, and the like, but is not limited thereto.

First, a light shielding layer BSM is disposed on the substrate 110. The light shielding layer BSM blocks light which is incident to active layers ACT of the plurality of transistors to reduce or minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of the substrate 110 or a type of transistor but is not limited thereto.

A driving transistor DT including an active layer ACT, a gate electrode GE, a source electrode SE, and a drain electrode DE is disposed on the buffer layer 111.

Even though it is not illustrated in FIG. 2B, an additional buffer layer may be disposed between the substrate 110 and the light shielding layer BSM. The additional buffer layer may be configured by a single layer or a double layer of silicon oxide (Siox) or silicon nitride (SiNx) to reduce permeation of moisture or impurities through the substrate 110, like the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed. The active layers of the transistors may also be formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, may be formed of the same material, or formed of different materials.

A gate insulating layer 112 is disposed on the active layer ACT. The gate insulating layer 112 is an insulating layer which electrically insulates the active layer ACT from the gate electrode GE and may be configured by a single layer or a double layer of silicon oxide (Siox) or silicon nitride (SiNx) but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

Further, a connection electrode CNT may be disposed on the gate insulating layer 112. The connection electrode CNT may be formed of the same material as the gate electrode GE and may be electrically connected to the source electrode SE.

A first interlayer insulating layer 113 and a second interlayer insulating layer 114 are disposed on the gate electrode GE. In the first interlayer insulating layer 113 and the second interlayer insulating layer 114, contact holes through which each of the source electrode SE and the drain electrode DE is connected to the active layer ACT are formed. The first interlayer insulating layer 113 and the second interlayer insulating layer 114 are insulating layers which protect components therebelow and may be configured by single layers or double layers of silicon oxide (Siox) or silicon nitride (SiNx) but are not limited thereto.

The storage capacitor Cst may be disposed on the gate insulating film 112. The storage capacitor Cst may be configured with a metal layer TM and a gate electrode GE as a capacitor electrode but is not limited thereto and may be implemented in various manners.

The metal layer TM may be disposed on the first interlayer insulating layer 113. The metal layer TM may be disposed so as to overlap the gate electrode GE with the first interlayer insulating layer 113 therebetween.

The source electrode SE and the drain electrode DE which are electrically connected to the active layer ACT are disposed on the second interlayer insulating layer 114. The drain electrode DE is electrically connected to the storage capacitor Cst and the second electrode 135 of the light emitting diode LED and the source electrode SE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

A first planarization layer 115 is disposed on the source electrode SE and the drain electrode DE. The first planarization layer 115 may planarize an upper portion of the pixel circuit including the driving transistor DT. The first planarization layer 115 may be configured by a single layer or a double layer, and for example, configured by benzocyclobutene or an acrylic organic material, but is not limited thereto.

A plurality of reflection plates RF may be disposed on the first planarization layer 115. Specifically, the plurality of reflection plates RF is disposed below the plurality of light emitting diodes LED to be electrically connected to the light emitting diodes, respectively.

The reflection plate RF is a configuration which reflects light emitted from the plurality of light emitting diodes LED above the substrate 110 and may be formed with a shape corresponding to each of the plurality of sub pixels SP. The reflection plate RF may reflect the light emitted from the light emitting diode LED and may also be used as an electrode which electrically connects the light emitting diode LED and the pixel circuit. That is, the reflection plate RF may electrically connect the first electrode 134 and the common power line VL.

Therefore, the reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide ITO, but the structure of the reflection plate RF is not limited thereto.

An intermediate electrode CE may be disposed on the first planarization layer 115. The intermediate electrode CE may be connected to the plurality of connection patterns CP and the drain electrode DE of the driving transistor DT through a contact hole. That is, the intermediate electrode CE may electrically connect the driving transistor DT disposed in the first sub pixel SP1 and the first light emitting diode LED1 or the driving transistor DT disposed in the second sub pixel SP2 and the second light emitting diode LED2. At this time, the intermediate electrode CE may be formed of the same material as the plurality of reflection plates RF but is not limited thereto.

The plurality of light emitting diodes LED is disposed in each of the plurality of sub pixels SP on the plurality of reflection plates RF. The light emitting diode LED is an element which emits light by a current and may include a red light emitting diode which emits red light, a green light emitting diode which emits green light, and a light emitting diode which emits blue light and may implement light with various colors including white by a combination thereof. For example, the light emitting diode LED may be a light emitting diode LED or a micro LED but is not limited thereto.

The first light emitting diode LED1 may be disposed in the first sub pixel SP1, the second light emitting diode LED2 may be disposed in the second sub pixel SP2, and the sharing light emitting diode LED′ may be disposed in the sharing sub pixel SP′. At this time, the first light emitting diode LED1, the second light emitting diode LED2, and the sharing light emitting diode LED′ may emit light with the same color. That is, all the first light emitting diode LED1, the second light emitting diode LED2, and the sharing light emitting diode LED′ may be red light emitting diodes, green light emitting diodes, or blue light emitting diodes. At this time, each of the first light emitting diode LED1 and the second light emitting diode LED2 is connected to a transistor of each of the first sub pixel SP1 and the second sub pixel SP2 to be individually driven. In contrast, the sharing light emitting diode LED′ of the sharing sub pixel SP′ may serve as an auxiliary light emitting diode of the first light emitting diode LED1 and the second light emitting diode LED2. Accordingly, the sharing light emitting diode LED′ may be driven by a transistor of the first sub pixel SP1 or the second sub pixel SP2 through the connection pattern CP. However, in the display device 100 according to the exemplary embodiment of the present disclosure, both the first light emitting diode LED1 and the second light emitting diode LED2 are normal and are normally transferred so that the sharing light emitting diode LED′ may not be used.

An adhesive layer CF is disposed between the plurality of light emitting diodes LED and the plurality of reflection plates RF. The adhesive layer CF may fix the light emitting diode LED disposed on the reflection plate RF. Further, the adhesive layer CF may be formed to include a conductive material to electrically connect the reflection plate RF and the first electrode 134 of the light emitting diode LED.

The plurality of light emitting diodes LED includes a first semiconductor layer 131, an emission layer 132, a second semiconductor layer 133, a first electrode 134, a second electrode 135, and a passivation film 136. In the present disclosure, it is illustrated that the plurality of light emitting diodes LED is vertical light emitting diodes, but it is not limited thereto.

The first semiconductor layer 131 is disposed on the adhesive layer CF and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but they are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 is disposed between the first semiconductor layer 131 and the adhesive layer CF. The first electrode 134 is an electrode which electrically connects the high potential power line VL and the first semiconductor layer 131. In this case, the first semiconductor layer 131 is a semiconductor layer doped with a p-type impurity and the first electrode 134 may be an anode. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the driving transistor DT and the second semiconductor layer 133. In this case, the second semiconductor layer 133 is a semiconductor layer doped with an n-type impurity and the second electrode 135 may be a cathode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The passivation film 136 is disposed on side walls of the first semiconductor layer 131, the emission layer 132, the second semiconductor layer 133, the first electrode 134, and the second electrode 135. The passivation film 136 encloses the first semiconductor layer 131, the emission layer 132, the second semiconductor layer 133, the first electrode 134, and the second electrode 135. The passivation film 136 is a film for protecting the first semiconductor layer 131, the emission layer 132, the second semiconductor layer 133, the first electrode 134, and the second electrode 135. For example, the passivation film 136 may be configured by transparent epoxy, silicon oxide (SiOx) or silicon nitride (SiNx), but is not limited thereto.

Next, a second planarization layer 121 and a third planarization layer 122 are disposed to enclose the light emitting diode LED.

The second planarization layer 121 overlaps parts of side surfaces of the plurality of light emitting diodes LED to fix and protect the plurality of light emitting diodes LED. For example, the second planarization layer 121 may be configured by benzocyclobutene or an acrylic organic material but is not limited thereto.

The third planarization layer 122 may be formed to cover an upper portion of the second planarization layer 121 and a part of the side surface of the light emitting diode LED. For example, the third planarization layer 122 may be configured by benzocyclobutene or an acrylic organic material but is not limited thereto.

A connection pattern CP and a common power line VL are disposed on the third planarization layer 122. The common power line VL may be electrically connected to the reflection plate RF disposed below the light emitting diode LED through a contact hole formed in the second planarization layer 121 and the third planarization layer 122. That is, the common power line VL is disposed at one side of the first sub pixel SP1, the second sub pixel SP2, and the sharing sub pixel SP′ to apply a common power to the first sub pixel SP1, the second sub pixel SP2, and the sharing sub pixel SP′. For example, the common power line VL may be a high potential power line which transmits a high potential power voltage but is not limited thereto.

The connection pattern CP may electrically connect the second electrode 135 of the light emitting diode LED and the driving transistor DT through a contact hole formed in the second planarization layer 121 and the third planarization layer 122. That is, in the display device 100 according to the exemplary embodiment of the present disclosure, the first light emitting diode LED1 and the second light emitting diode LED2 normally operate. Therefore, in order to individually drive of the first light emitting diode and the second light emitting diode, the first connection pattern CP1 and a second connection pattern CP2 of the connection pattern CP may be disposed to be spaced apart from each other. That is, the first connection pattern CP1 disposed at the other side of the first sub pixel SP1 may connect the driving transistor DT and the first light emitting diode LED1 disposed in the first sub pixel SP1. The second connection pattern CP2 disposed at the other side of the second sub pixel SP2 may connect the driving transistor DT and the second light emitting diode LED2 disposed in the second sub pixel SP2.

A dummy pattern DP which is connected to the sharing light emitting diode LED′ may be disposed on the same layer as the connection pattern CP. Therefore, the dummy pattern DP may be formed of the same material as the plurality of connection patterns CP. When the first sub pixel SP1 and the second sub pixel SP2 are normal, the sharing light emitting diode LED′ disposed in the sharing sub pixel SP′ does not need to be driven. Accordingly, the sharing light emitting diode LED′ does not need to be connected to the driving transistor DT disposed in the first sub pixel SP1 or the second sub pixel SP2, the dummy pattern DP may be disposed to be spaced apart from the first connection pattern CP1 and the second connection pattern CP2. Accordingly, the dummy pattern DP may be disposed to be floated.

Generally, in the plurality of sub pixels disposed on the substrate, a defective sub pixel which does not normally emit light may be generated. For example, when the light emitting diode itself is defective or the light emitting diode is not normally transferred, the corresponding sub pixel may become a defective sub pixel. Therefore, in order to prepare for the occurrence of a defective sub pixel, an additional sub pixel which emits the same light as each of the plurality of sub pixels is disposed. For example, when the plurality of sub pixels is configured by a red sub pixel, a green sub pixel, and a blue sub pixel, two red sub pixels which emit light based on the same data signal, two green sub pixels which emit light based on the same data signal, and two blue sub pixels which emit light based on the same data signal are disposed on the substrate. Therefore, even though one red sub pixel is a defective sub pixel, another red sub pixel emits light to suppress the defect of the entire display device. However, when the display device is configured as described above, in order to ensure a placement space of the additional sub pixel, a separate additional area is required so that it is difficult to implement a high resolution display device. Further, as the number of light emitting diodes to be transferred to the display device is doubled, the manufacturing cost of the display device is also significantly increased.

Therefore, during an initial manufacturing process of the display device, the light emitting diode is not transferred twice in advance, but only an area for performing a repair process later is left to manufacture the display device. That is, when one sub pixel is a defective sub pixel, a repair process is used to transfer the light emitting diode which emits light with the same color as a color emitted by the sub pixel to an area in which the repair process is performed. In this case, the light emitting diode is not initially transferred twice so that the manufacturing cost of the display device may be reduced more than that as described above. However, there may be a limitation in a type of a light emitting diode for performing the repair process. Further, a flip chip-type light emitting diode is generally used to perform the repair process. When the initially transferred light emitting diode is a vertical type or a lateral type, the type of the light emitting diode is different so that the emission characteristic may be different. Further, there is a disadvantage in that it is difficult for the flip chip type-light emitting diode to reduce the size of the light emitting diode in terms of electrode connection or transferring.

Therefore, in the display device 100 according to the exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, in the display device 100 according to the exemplary embodiment of the present disclosure, it is necessary to transfer 1.5 times as many light emitting diodes LED as the minimum number of light emitting diodes LED required to display an image. Therefore, the manufacturing yield of the display device 100 may be improved and the manufacturing cost of the display device 100 may be reduced.

Further, in the display device 100 according to the exemplary embodiment of the present disclosure, the first sub pixel SP1 and the second sub pixel SP2 are not defined to have individual auxiliary sub pixels but share one sharing sub pixel SP′ so that a design area may be ensured. For example, when all the individual sub pixels have auxiliary sub pixels, a total of six sub pixels may be defined as one pixel. However, in the display device 100 according to the exemplary embodiment of the present disclosure, the first sub pixel SP1 and the second sub pixel SP2 share one sharing sub pixel SP′ so that a total of 4.5 sub pixels SP may be defined as one pixel. Therefore, an area occupied by one pixel is reduced so that the number of sub pixels SP included in the display device 100 may be increased so that the high resolution display device can be implemented.

Hereinafter, a display device according to various exemplary embodiments of the present disclosure in which a defective light emitting diode is disposed in the first sub pixel or the second sub pixel or the light emitting diode is defectively transferred will be described.

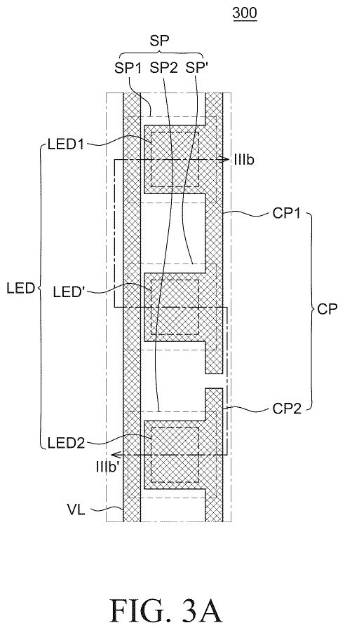

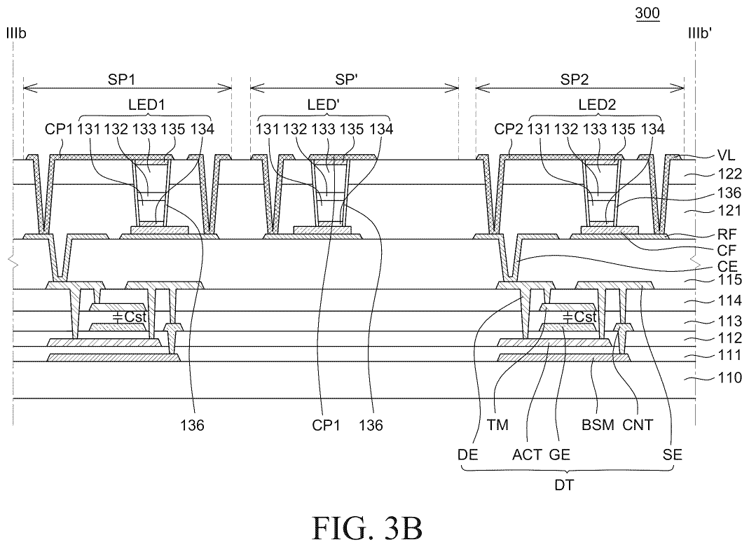

FIG. 3A is a plan view of a pixel area of a display device according to another exemplary embodiment of the present disclosure. FIG. 3B is a cross-sectional view taken along the line IIIb-IIIb′ of FIG. 3A. In FIGS. 3A and 3B, it is illustrated that the light emitting diodes disposed in the first sub pixel SP1, the second sub pixel SP2, and the sharing sub pixel SP′ are normally transferred, but only the first light emitting diode LED1 is defective. In FIG. 3A, for the convenience of description, among various components of the display device 300, only a light emitting diode LED, a common power line VL, and a connection pattern CP are illustrated. In the display device 300 of FIGS. 3A and 3B, only when the first light emitting diode LED1 is defective, presence of the dummy pattern DP, and the connection pattern DP are different from those of the display device 100 of FIGS. 1 to 2B, but other components are substantially the same. Therefore, a redundant description will be omitted.

Referring to FIGS. 3A and 3B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 300 according to another exemplary embodiment of the present disclosure, the first light emitting diode LED1 is defective so that the first sub pixel SP1 does not emit light. Therefore, instead of the first light emitting diode LED1 disposed in the first sub pixel SP1, the sharing light emitting diode LED′ disposed in the sharing sub pixel SP′ may be driven. Specifically, the first connection pattern CP1 may electrically connect the driving transistor DT disposed in the first sub pixel SP1 and the sharing light emitting diode LED′. Therefore, the sharing light emitting diode LED′ may be electrically connected to the driving T through the first connection pattern CP1 and the intermediate electrode CE. Further, the second connection pattern CP2 may electrically connect the driving transistor DT disposed in the second sub pixel SP2 and the second light emitting diode LED2. Therefore, the first connection pattern CP1 and the second connection pattern CP2 may be disposed to be spaced apart from each other.

In the display device 300 according to another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 300 may be improved and the manufacturing cost of the display device 300 may be reduced.

Further, in the display device 300 according to another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 300 may be increased so that the high resolution display device can be implemented.

In the display device 300 according to another exemplary embodiment of the present disclosure, when the first light emitting diode LED1 disposed in the first sub pixel SP1 is defective, the sharing light emitting diode LED′ disposed in the sharing sub pixel SP′ is driven instead to replace the defective sub pixel to emit light. Specifically, the first connection pattern CP1 may electrically connect the driving transistor DT disposed in the first sub pixel SP1 and the sharing light emitting diode LED′ to drive the sharing light emitting diode LED′ disposed in the sharing sub pixel SP′. That is, the sharing sub pixel SP′ may be driven as an auxiliary sub pixel of the first sub pixel SP1 through the first connection pattern CP1 without a separate pixel circuit in the sharing sub pixel SP′ in which the sharing light emitting diode LED′ is disposed. Accordingly, in the display device 300 according to another exemplary embodiment of the present disclosure, the sharing sub pixel SP′ which is an auxiliary sub pixel may be driven without separate position programming to allow the sharing sub pixel SP′ to emit light. Further, in the display device 300 according to another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels SP.

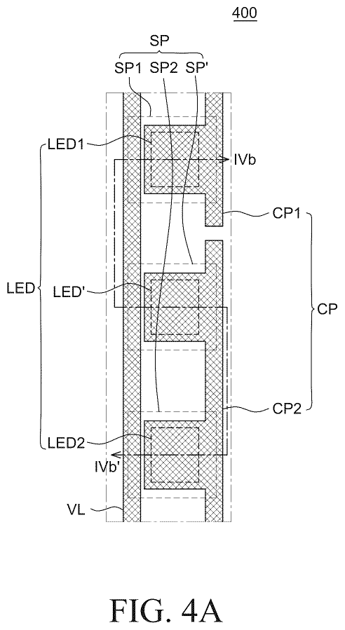

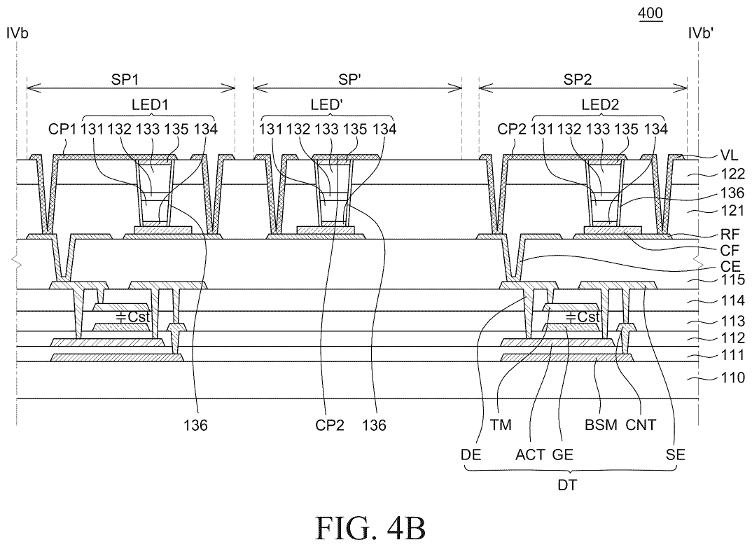

FIG. 4A is a plan view of a pixel area of a display device according to still another exemplary embodiment of the present disclosure. FIG. 4B is a cross-sectional view taken along the line IVb-IVb′ of FIG. 4A. In FIGS. 4A and 4B, it is illustrated that the light emitting diodes LED disposed in the first sub pixel SP1, the second sub pixel SP2, and the sharing sub pixel SP′ are normally transferred, but only the second light emitting diode LED2 is defective. In FIG. 4A, for the convenience of description, among various components of the display device 400, only a light emitting diode LED, a common power line VL, and a connection pattern CP are illustrated. In the display device 400 of FIGS. 4A and 4B, only whether the second light emitting diode LED2 is defective, presence of the dummy pattern DP, and the connection pattern DP are different from those of the display device 100 of FIGS. 1 to 2B, but other components are substantially the same. Therefore, a redundant description will be omitted.

Referring to FIGS. 4A and 4B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 400 according to still another exemplary embodiment of the present disclosure, the second light emitting diode LED2 is defective so that the second sub pixel SP2 does not emit light. Therefore, instead of the second light emitting diode LED2 disposed in the second sub pixel SP2, the sharing light emitting diode LED′ disposed in the sharing sub pixel SP′ may be driven. Specifically, the second connection pattern CP2 may electrically connect the driving transistor DT disposed in the second sub pixel SP2 and the sharing light emitting diode LED′. Therefore, the sharing light emitting diode LED′ may be electrically connected to the driving transistor DT through the second connection pattern CP2 and the intermediate electrode CE. Further, the first connection pattern CP1 may electrically connect the driving transistor DT disposed in the first sub pixel SP1 and the first light emitting diode LED1. Therefore, the first connection pattern CP1 and the second connection pattern CP2 may be disposed to be spaced apart from each other.

In the display device 400 according to still another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 400 may be improved and the manufacturing cost of the display device 400 may be reduced.

Further, in the display device 400 according to still another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 400 may be increased so that the high resolution display device can be implemented.

In the display device 400 according to still another exemplary embodiment of the present disclosure, when the second light emitting diode LED2 disposed in the second sub pixel SP2 is defective, the sharing light emitting diode LED′ disposed in the sharing sub pixel SP′ is driven instead to repair the defective sub pixel. Specifically, the second connection pattern CP2 may electrically connect the driving transistor DT disposed in the second sub pixel SP2 and the sharing light emitting diode LED′ to drive the sharing light emitting diode LED′ disposed in the sharing sub pixel SP′. That is, the sharing sub pixel SP′ may be driven as an auxiliary sub pixel of the second sub pixel SP2 through the second connection pattern CP2 without a separate pixel circuit in the sharing sub pixel SP′ in which the sharing light emitting diode LED′ is disposed. Accordingly, in the display device 400 according to still another exemplary embodiment of the present disclosure, the sharing sub pixel SP′ which is an auxiliary sub pixel may be driven without separate position programming to allow the sharing sub pixel SP′ to emit light. Further, in the display device 400 according to still another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels SP.

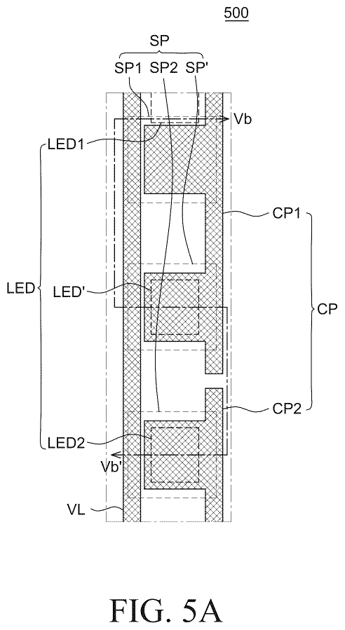

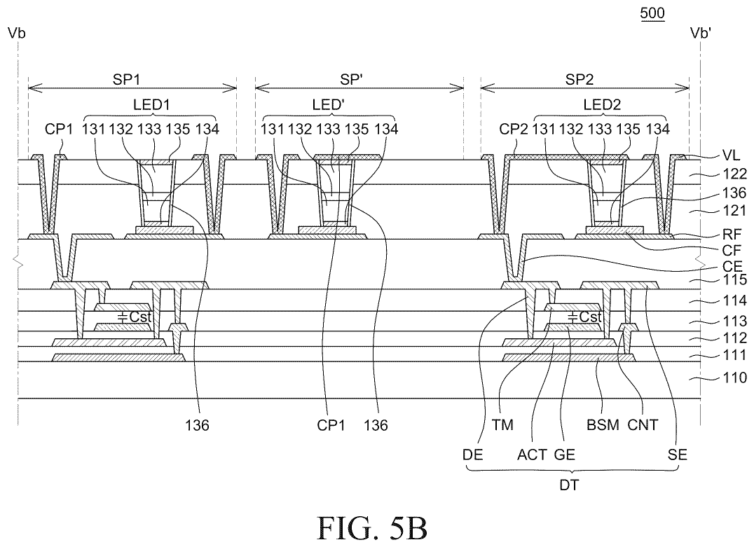

FIG. 5A is a plan view of a pixel area of a display device according to still another exemplary embodiment of the present disclosure. FIG. 5B is a cross-sectional view taken along the line Vb-Vb′ of FIG. 5A. In FIGS. 5A and 5B, it is illustrated that all the light emitting diodes disposed in the second sub pixel SP2 and the sharing sub pixel SP′ are normal and the light emitting diodes are also normally transferred, but the first light emitting diode LED1 is erroneously transferred to the first sub pixel SP1 to be deviated from a normal position. In FIG. 5A, for the convenience of description, among various components of the display device 500, only a light emitting diode LED, a common power line VL, and a connection pattern CP are illustrated. In the display device 500 of FIGS. 5A and 5B, only whether the first light emitting diode LED1 is erroneously transferred, presence of the dummy pattern DP, and the connection pattern DP are different from those of the display device 100 of FIGS. 1 to 2B, but other components are substantially the same. Therefore, a redundant description will be omitted.

Referring to FIGS. 5A and 5B, the first light emitting diode LED1 is erroneously transferred so that the first light emitting diode LED1 is not connected to the first connection pattern CP1. Therefore, the first light emitting diode LED1 may not be connected to the driving transistor DT disposed in the first sub pixel SP1 and may not emit light. Therefore, in the display device 500 according to still another exemplary embodiment of the present disclosure, the sharing sub pixel SP′ may emit light, instead of the first sub pixel. In the meantime, in FIGS. 5A and 5B, it is illustrated that the first light emitting diode LED1 is not connected to the first connection pattern CP1. However, even though the first light emitting diode LED1 is connected to the first connection pattern CP1, when sufficient connection for driving the first light emitting diode LED1 is not provided, the sharing sub pixel SP′ may emit light, instead of the first sub pixel SP1.

Referring to FIGS. 5A and 5B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 500 according to still another exemplary embodiment of the present disclosure, the first light emitting diode LED1 is erroneously transferred and is not connected to the driving transistor DT so that the first sub pixel SP1 does not emit light. Therefore, instead of the first light emitting diode LED1 disposed in the first sub pixel SP1, the sharing light emitting diode LED′ disposed in the sharing sub pixel SP′ may be driven. Specifically, the first connection pattern CP1 may electrically connect the driving transistor DT disposed in the first sub pixel SP1 and the sharing light emitting diode LED′. Therefore, the sharing t emitting diode LED′ may be electrically connected to the driving transistor DT through the first connection pattern CP1 and the intermediate electrode CE. Further, the second connection pattern CP2 may electrically connect the driving transistor DT disposed in the second sub pixel SP2 and the second light emitting diode LED2. Therefore, the first connection pattern CP1 and the second connection pattern CP2 may be disposed to be spaced apart from each other.

In the display device 500 according to still another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 500 may be improved and the manufacturing cost of the display device 500 may be reduced.

Further, in the display device 500 according to still another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 500 may be increased so that the high resolution display device can be implemented.

In the display device 500 according to still another exemplary embodiment of the present disclosure, when the first light emitting diode LED1 disposed in the first sub pixel SP1 is erroneously transferred, the sharing light emitting diode LED′ disposed in the sharing sub pixel SP′ is driven instead to repair the defective sub pixel. Specifically, the first connection pattern CP1 may electrically connect the driving transistor DT disposed in the first sub pixel SP1 and the sharing light emitting diode LED′ to drive the sharing light emitting diode LED′ disposed in the sharing sub pixel SP′. That is, the sharing sub pixel SP′ may be driven as an auxiliary sub pixel of the first sub pixel SP1 through the first connection pattern CP1 without a separate pixel circuit in the sharing sub pixel SP′ in which the sharing light emitting diode LED′ is disposed.

Accordingly, in the display device 500 according to still another exemplary embodiment of the present disclosure, the sharing sub pixel SP′ which is an auxiliary sub pixel may be driven without separate position programming to allow the sharing sub pixel SP′ to emit light. Further, in the display device 500 according to still another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels SP.

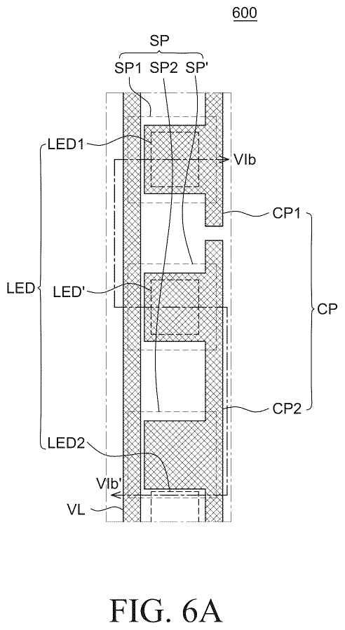

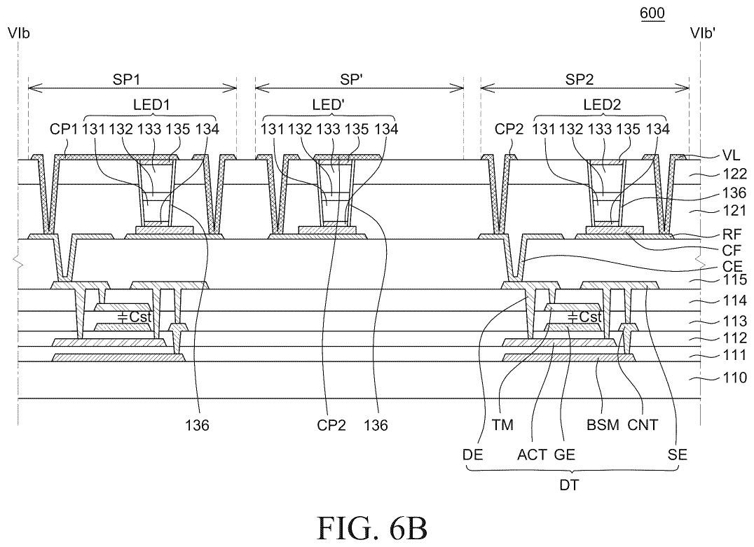

FIG. 6A is a plan view of a pixel area of a display device according to still another exemplary embodiment of the present disclosure. FIG. 6B is a cross-sectional view taken along the line VIb-VIb′ of FIG. 6A. In FIGS. 6A and 6B, it is illustrated that all the light emitting diodes disposed in the first sub pixel SP1 and the sharing sub pixel SP′ are normal and the light emitting diodes are also normally transferred, but the second light emitting diode LED2 is erroneously transferred to the second sub pixel SP2 to be deviated from a normal position. In FIG. 6A, for the convenience of description, among various components of the display device 600, only a light emitting diode LED, a common power line VL, and a connection pattern CP are illustrated. In the display device 600 of FIGS. 6A and 6B, only whether the second light emitting diode LED2 is erroneously transferred, presence of the dummy pattern DP, and the connection pattern DP are different from those of the display device 100 of FIGS. 1 to 2B, but other components are substantially the same. Therefore, a redundant description will be omitted.

Referring to FIGS. 6A and 6B, the second light emitting diode LED2 is erroneously transferred so that the second light emitting diode LED2 is not connected to the second connection pattern CP2. Therefore, the second light emitting diode LED2 may not be connected to the driving transistor DT disposed in the second sub pixel SP2 and may not emit light. Therefore, in the display device 600 according to still another exemplary embodiment of the present disclosure, the sharing sub pixel SP′ may emit light, instead of the second sub pixel SP2. In the meantime, in FIGS. 6A and 6B, it is illustrated that the second light emitting diode LED2 is not connected to the second connection pattern CP2. However, even though the second light emitting diode LED2 is connected to the second connection pattern CP2, when sufficient connection for driving the second light emitting diode LED2 is not provided, the sharing sub pixel SP′ may emit light, instead of the second sub pixel SP2.

Referring to FIGS. 6A and 6B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 600 according to still another exemplary embodiment of the present disclosure, the second light emitting diode LED2 is erroneously transferred, and is not connected to the driving transistor DT so that the second sub pixel SP2 does not emit light. Therefore, instead of the second light emitting diode LED2 disposed in the second sub pixel SP2, the sharing light emitting diode LED′ disposed in the sharing sub pixel SP′ may be driven. Specifically, the second connection pattern CP2 may electrically connect the driving transistor DT disposed in the second sub pixel SP2 and the sharing light emitting diode LED′. Therefore, the sharing light emitting diode LED′ may be electrically connected to the driving transistor DT through the second connection pattern CP2 and the intermediate electrode CE. Further, the first connection pattern CP1 may electrically connect the driving transistor DT disposed in the first sub pixel SP1 and the first light emitting diode LED1. Therefore, the first connection pattern CP1 and the second connection pattern CP2 may be disposed to be spaced apart from each other.

In the display device 600 according to still another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 600 may be improved and the manufacturing cost of the display device 600 may be reduced.

Further, in the display device 600 according to still another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 600 may be increased so that the high resolution display device can be implemented.

In the display device 600 according to still another exemplary embodiment of the present disclosure, when the second light emitting diode LED2 disposed in the second sub pixel SP2 is erroneously transferred, the sharing light emitting diode LED′ disposed in the sharing sub pixel SP′ is driven instead to repair the defective sub pixel. Specifically, the second connection pattern CP2 may electrically connect the driving transistor DT disposed in the second sub pixel SP2 and the sharing light emitting diode LED′ to drive the sharing light emitting diode LED′ disposed in the sharing sub pixel SP′. That is, the sharing sub pixel SP′ may be driven as an auxiliary sub pixel of the second sub pixel SP2 through the second connection pattern CP2 without a separate pixel circuit in the sharing sub pixel SP′ in which the sharing light emitting diode LED′ is disposed. Accordingly, in the display device 600 according to still another exemplary embodiment of the present disclosure, the sharing sub pixel SP′ which is an auxiliary sub pixel may be driven without separate position programming to allow the sharing sub pixel SP′ to emit light. Further, in the display device 600 according to still another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels SP.

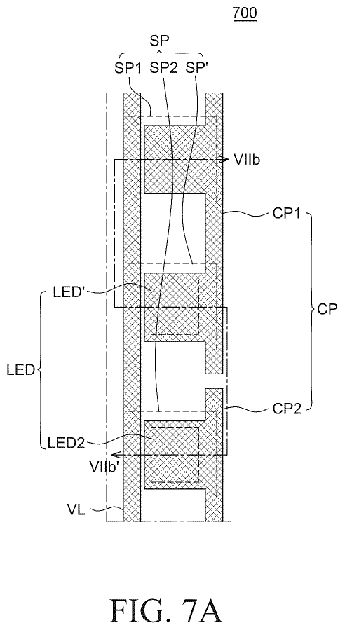

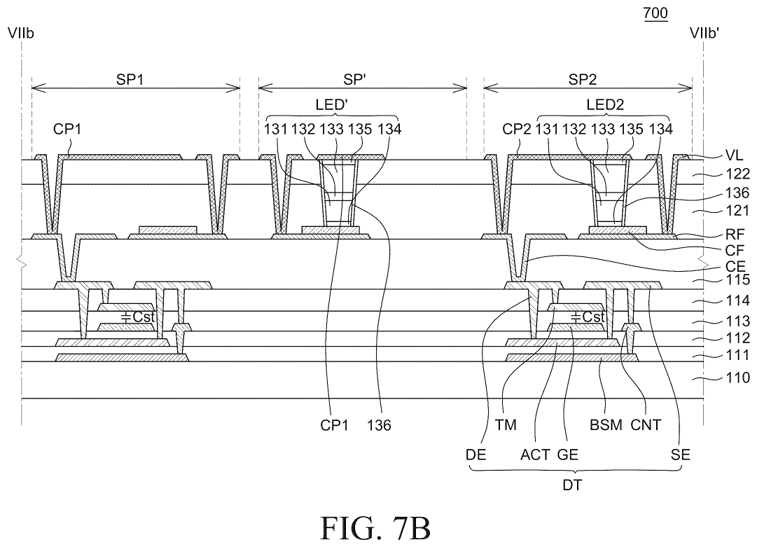

FIG. 7A is a plan view of a pixel area of a display device according to still another exemplary embodiment of the present disclosure. FIG. 7B is a cross-sectional view taken along the line VIIb-VIIb′ of FIG. 7A. In FIGS. 7A and 7B, it is illustrated that all the light emitting diodes disposed in the second sub pixel SP2 and the sharing sub pixel SP′ are normal and the light emitting diodes are also normally transferred, but the first light emitting diode LED1 is not transferred to the first sub pixel SP1. In FIG. 7A, for the convenience of description, among various components of the display device 700, only a light emitting diode LED, a common power line VL, and a connection pattern CP are illustrated. In the display device 700 of FIGS. 7A and 7B, only whether the first light emitting diode LED1 is not transferred, presence of the dummy pattern DP, and the connection pattern DP are different from those of the display device 100 of FIGS. 1 to 2B, but other components are substantially the same. Therefore, a redundant description will be omitted.

Referring to FIGS. 7A and 7B, the first light emitting diode LED1 is not transferred so that the light emitting diode is not disposed on the reflection plate RF of the first sub pixel SP1. Accordingly, the second planarization layer 121 and the third planarization layer 122 are disposed on the reflection plate of the first sub pixel SP1. Therefore, the first sub pixel SP1 may not emit light. Therefore, in the display device 700 according to still another exemplary embodiment of the present disclosure, the sharing sub pixel SP′ may emit light, instead of the first sub pixel SP1.

Referring to FIGS. 7A and 7B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 700 according to still another exemplary embodiment of the present disclosure, the first light emitting diode LED1 is not transferred so that the first sub pixel SP1 does not emit light. Therefore, instead of the first light emitting diode LED1, the sharing light emitting diode LED′ disposed in the sharing sub pixel SP′ may be driven. Specifically, the first connection pattern CP1 may electrically connect the driving transistor DT disposed in the first sub pixel SP1 and the sharing light emitting diode LED′. Therefore, the sharing light emitting diode LED′ may be electrically connected to the driving transistor DT through the first connection pattern CP1 and the intermediate electrode CE. Further, the second connection pattern CP2 may electrically connect the driving transistor DT disposed in the second sub pixel SP2 and the second light emitting diode LED2. Therefore, the first connection pattern CP1 and the second connection pattern CP2 may be disposed to be spaced apart from each other.

In the display device 700 according to still another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 700 may be improved and the manufacturing cost of the display device 700 may be reduced.

Further, in the display device 700 according to still another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 700 may be increased so that the high resolution display device can be implemented.

In the display device 700 according to still another exemplary embodiment of the present disclosure, when the first light emitting diode LED1 is not transferred to the first sub pixel SP1, the sharing light emitting diode LED′ disposed in the sharing sub pixel SP′ is driven instead to repair the defective sub pixel. Specifically, the first connection pattern CP1 may electrically connect the driving transistor DT disposed in the first sub pixel SP1 and the sharing light emitting diode LED′ to drive the sharing light emitting diode LED′ disposed in the sharing sub pixel SP′. That is, the sharing sub pixel SP′ may be driven as an auxiliary sub pixel of the first sub pixel SP1 through the first connection pattern CP1 without a separate pixel circuit in the sharing sub pixel SP′ in which the sharing light emitting diode LED′ is disposed. Accordingly, in the display device 700 according to still another exemplary embodiment of the present disclosure, the sharing sub pixel SP′ which is an auxiliary sub pixel may be driven without separate position programming to allow the sharing sub pixel SP′ to emit light. Further, in the display device 700 according to still another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels SP.

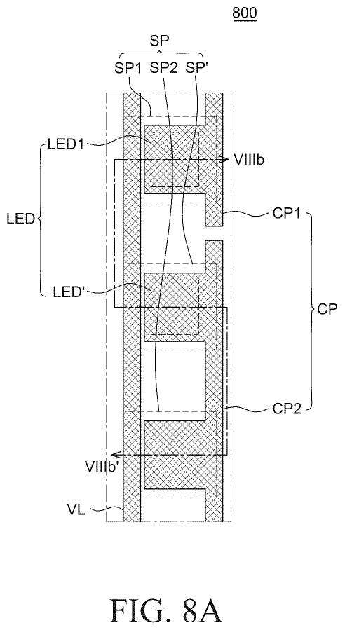

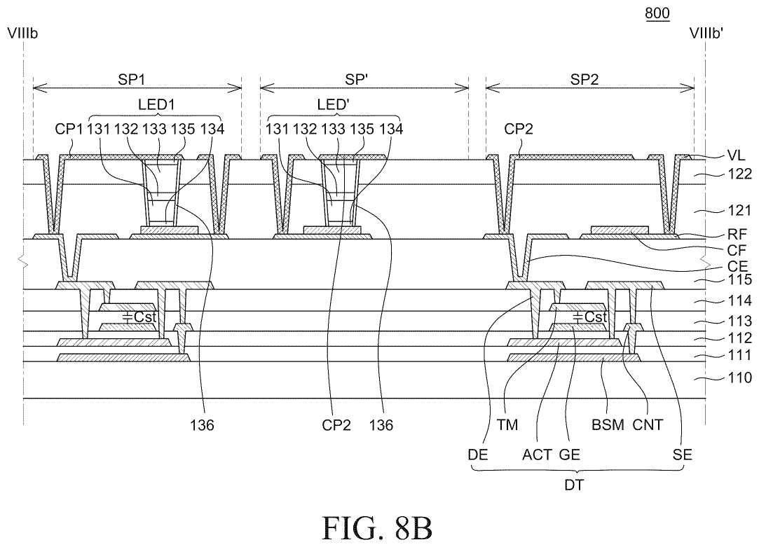

FIG. 8A is a plan view of a pixel area of a display device according to still another exemplary embodiment of the present disclosure. FIG. 8B is a cross-sectional view taken along the line VIIIb-VIIIb′ of FIG. 8A. In FIGS. 8A and 8B, it is illustrated that all the light emitting diodes disposed in the first sub pixel SP1 and the sharing sub pixel SP′ are normal and the light emitting diodes are also normally transferred, but the second light emitting diode LED2 is not transferred to the second sub pixel SP2. In FIG. 8A, for the convenience of description, among various components of the display device 800, only a light emitting diode LED, a common power line VL, and a connection pattern CP are illustrated. In the display device 800 of FIGS. 8A and 8B, only whether the second light emitting diode LED2 is not transferred, presence of the dummy pattern DP, and the connection pattern DP are different from those of the display device 100 of FIGS. 1 to 2B, but other components are substantially the same. Therefore, a redundant description will be omitted.

Referring to FIGS. 8A and 8B, the second light emitting diode LED2 is not transferred so that the light emitting diode LED is not disposed on the reflection plate RF of the second sub pixel SP2. Accordingly, the second planarization layer 121 and the third planarization layer 122 are disposed on the reflection plate RF of the second sub pixel SP2. Therefore, the second sub pixel SP2 may not emit light. Therefore, in the display device 800 according to still another exemplary embodiment of the present disclosure, the sharing sub pixel SP′ may emit light, instead of the second sub pixel SP2.

Referring to FIGS. 8A and 8B, the connection pattern CP is disposed on the third planarization layer 122. The connection pattern CP may electrically connect the second electrode 135 of the light emitting diode LED and the driving transistor DT through a contact hole formed in the second planarization layer 121 and the third planarization layer 122. In the display device 800 according to still another exemplary embodiment of the present disclosure, the second light emitting diode LED2 is not transferred so that the second sub pixel SP2 does not emit light. Therefore, instead of the second light emitting diode LED2, the sharing light emitting diode LED′ disposed in the sharing sub pixel SP′ may be driven. Specifically, the second connection pattern CP2 may electrically connect the driving transistor DT disposed in the second sub pixel SP2 and the sharing light emitting diode LED′. Therefore, the sharing light emitting diode LED′ may be electrically connected to the driving transistor DT through the second connection pattern CP2 and the intermediate electrode CE. Further, the first connection pattern CP1 may electrically connect the driving transistor DT disposed in the first sub pixel SP1 and the first light emitting diode LED1. Therefore, the first connection pattern CP1 and the second connection pattern CP2 may be disposed to be spaced apart from each other.

In the display device 800 according to still another exemplary embodiment of the present disclosure, the first sub pixel SP1 and the second sub pixel SP2 which emit the same color of light and are adjacent to each other may share the sharing sub pixel SP′ disposed between the first sub pixel SP1 and the second sub pixel SP2 as an auxiliary sub pixel. Accordingly, the manufacturing yield of the display device 800 may be improved and the manufacturing cost of the display device 800 may be reduced.

Further, in the display device 800 according to still another exemplary embodiment of the present disclosure, the first sub pixel SP1 and the second sub pixel SP2 are not defined to have individual auxiliary sub pixels but share one sharing sub pixel SP′ so that a design area may be ensured. Therefore, an area occupied by one pixel is reduced so that the number of sub pixels SP included in the display device 800 may be increased so that the high resolution display device can be implemented.

In the display device 800 according to still another exemplary embodiment of the present disclosure, when the second light emitting diode LED2 disposed in the second sub pixel SP2 is not transferred, the sharing light emitting diode LED′ disposed in the sharing sub pixel SP′ is driven instead to repair the defective sub pixel. Specifically, the second connection pattern CP2 may electrically connect the driving transistor DT disposed in the second sub pixel SP2 and the sharing light emitting diode LED′ to drive the sharing light emitting diode LED′ disposed in the sharing sub pixel SP′. That is, the sharing sub pixel SP′ may be driven as an auxiliary sub pixel of the second sub pixel SP2 through the second connection pattern CP2 without a separate pixel circuit in the sharing sub pixel SP′ in which the sharing light emitting diode LED′ is disposed. Accordingly, in the display device 800 according to still another exemplary embodiment of the present disclosure, the sharing sub pixel SP′ which is an auxiliary sub pixel may be driven without separate position programming to allow the sharing sub pixel SP′ to emit light. Further, in the display device 800 according to still another exemplary embodiment of the present disclosure, only one light emitting diode LED is turned on per sub pixel SP so that the sharing sub pixel SP′ is used as an auxiliary sub pixel to repair the defective pixel without luminance compensation between sub pixels.

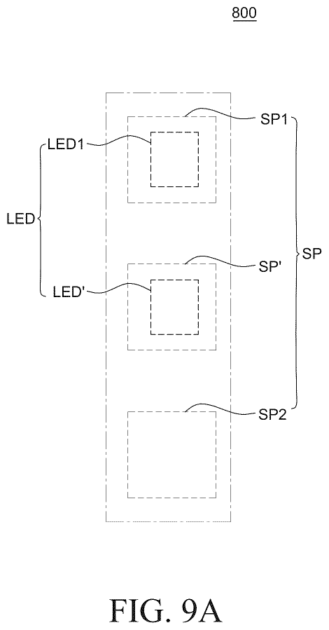

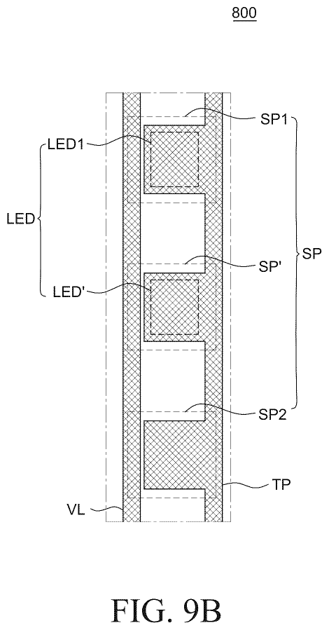

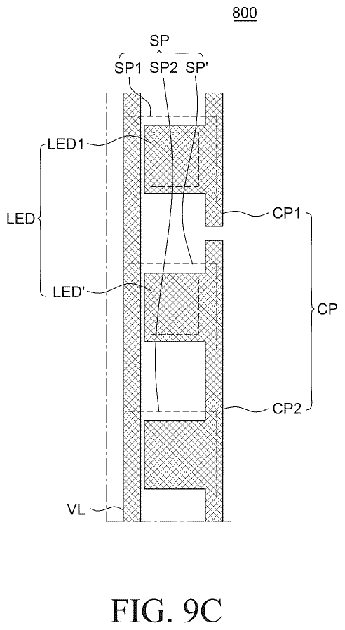

Hereinafter, a manufacturing method of a display device 800 according to an exemplary embodiment of the present disclosure will be described in detail with reference to FIGS. 9A to 9C.

FIGS. 9A to 9C are schematic process diagrams for explaining a manufacturing method of a display device according to an exemplary embodiment of the present invention. Like FIGS. 8A and 8B, in FIGS. 9A to 9C, it is illustrated that all the light emitting diodes LEDs disposed in the first sub pixel SP1 and the sharing sub pixel SP′ are normal and the light emitting diode LED is also normally transferred, but the second light emitting diode LED2 is not transferred to the second sub pixel SP2. For the convenience of description, among various components of the display device 800, in FIG. 9A, only a light emitting diode LED is illustrated and in FIGS. 9B and 9C, only a light emitting diode LED, a common power line VL, a connection pattern CP, and a temporary pattern TP are illustrated. In FIGS. 9A to 9C, only a temporary pattern TP is added to FIGS. 8A and 8B, but other components are substantially the same so that a redundant description will be omitted.

First, referring to FIGS. 9A and 9B, after transferring the plurality of light emitting diodes LED on the plurality of sub pixels SP, a common power line VL may be disposed at one side and the temporary pattern TP may be disposed at the other side.

The temporary pattern TP is disposed at the other sides of the first sub pixel SP1, the second sub pixel SP2, and the sharing sub pixel SP′ to simultaneously turn on the first sub pixel SP1, the second sub pixel SP2, and the sharing sub pixel SP′ to detect a defective sub pixel SP. For example, when the lighting test is performed by supplying a power source to the common power line VL and the temporary pattern TP, if the light emitting diode LED is normal and is normally transferred, the light emitting diode LED may emit light. As described above, the second light emitting diode LED2 is not transferred to the second sub pixel SP2 so that the second sub pixel may not emit light.

Even though in FIGS. 9A and 9B, it is illustrated that the second light emitting diode LED2 is not transferred to the second sub pixel SP2, it is not limited thereto. Therefore, when any one of the first light emitting diode LED1 and the second light emitting diode LED2 is defective, or any one is erroneously transferred, or any one is not transferred, the present disclosure may be applied in the same way.

Referring to FIG. 9C, the second sub pixel SP2 is defective so that the sharing sub pixel SP′ may be driven as an auxiliary sub pixel of the second sub pixel SP2. Therefore, the temporary pattern TP may be patterned as the first connection pattern CP1 and the second connection pattern CP2 to allow the first sub pixel SP1 and the sharing sub pixel SP′ which are normal to be individually driven. Specifically, the temporary pattern TP may be patterned as the first connection pattern CP1 and the second connection pattern CP2. Therefore, the first sub pixel SP1 may be driven by the driving transistor DT disposed in the first sub pixel SP1 through the first connection pattern CP1 and the sharing sub pixel SP′ may be driven by the driving transistor DT disposed in the second sub pixel SP2 through the second connection pattern CP2. At this time, the temporary pattern TP commonly disposed in the plurality of sub pixels SP is patterned as the first connection pattern CP1 and the second connection pattern CP2 so that a length of the plurality of connection patterns CP may be longer than a width of one sub pixel SP.

The exemplary embodiments of the present disclosure can also be described as follows:

According to an aspect of the present disclosure, there is provided a display device. The display device includes a substrate which includes a plurality of sub pixels including a first sub pixel, a second sub pixel, and a sharing sub pixel disposed between the first sub pixel and the second sub pixel, a plurality of transistors which is disposed in the first sub pixel and the second sub pixel, among the plurality of sub pixels, a common power line which is disposed at one sides of the first sub pixel, the second sub pixel, and the sharing sub pixel to apply a common power to the first sub pixel, the second sub pixel, and the sharing sub pixel and a plurality of connection patterns which is connected to the plurality of transistors, respectively, to be disposed at the other sides of the first sub pixel and the second sub pixel and is spaced apart from each other.

The first sub pixel, the second sub pixel, and the sharing sub pixel may emit light with the same color.

The display device may further include an intermediate electrode which connects the plurality of transistors and the plurality of connection patterns and a plurality of reflection plates connected to the common power line. The intermediate electrode and the plurality of reflection plates may be disposed on the same layer and are formed of the same material.

The display device may further include a plurality of light emitting diodes which includes a first light emitting diode disposed in the first sub pixel and a second light emitting diode disposed in the second sub pixel. The plurality of light emitting diodes may be disposed on the plurality of reflection plates to be electrically connected to the plurality of reflection plates. The plurality of connection patterns may include a first connection pattern which connects a transistor disposed in the first sub pixel, among the plurality of transistors, and the first light emitting diode and a second connection pattern which connects a transistor disposed in the second sub pixel, among the plurality of transistors, and the second light emitting diode.

The display device may further include a dummy pattern which is disposed at the other side of the sharing sub pixel and is disposed on the same layer and is formed of the same material as the plurality of connection patterns, and is spaced apart from the plurality of connection patterns. The plurality of light emitting diodes may further include a sharing light emitting diode which is disposed on the sharing sub pixel and is connected to the dummy pattern.

The display device may further include a plurality of light emitting diodes which includes a first light emitting diode disposed in the first sub pixel, a second light emitting diode disposed in the second sub pixel, and a sharing light emitting diode disposed in the sharing sub pixel. The sharing light emitting diode may be electrically connected to a transistor disposed in the first sub pixel or a transistor disposed in the second sub pixel, among the plurality of transistors.

The plurality of light emitting diodes may be disposed on the plurality of reflection plates to be electrically connected to the plurality of reflection plates. When the first light emitting diode, between the first light emitting diode and the second light emitting diode, is defective the plurality of connection patterns may include a first connection pattern which connects a transistor disposed in the first sub pixel, among the plurality of transistors and the sharing light emitting diode and a second connection pattern which connects a transistor disposed in the second sub pixel, among the plurality of transistors, and the second light emitting diode.

The plurality of light emitting diodes may be disposed on the plurality of reflection plates to be electrically connected to the plurality of reflection plates. When the second light emitting diode, between the first light emitting diode and the second light emitting diode, is defective, the plurality of connection patterns may include a first connection pattern which connects a transistor disposed in the first sub pixel, among the plurality of transistors and the first light emitting diode and a second connection pattern which connects a transistor disposed in the second sub pixel, among the plurality of transistors, and the sharing light emitting diode.

The first light emitting diode may be electrically insulated from at least one of the plurality of connection patterns and the plurality of reflection plates. The second light emitting diode and the sharing light emitting diode may be disposed on the plurality of reflection plates to be electrically connected to the plurality of reflection plates. The plurality of connection patterns may include a first connection pattern which connects a transistor disposed in the first sub pixel, among the plurality of transistors and the sharing light emitting diode and a second connection pattern which connects a transistor disposed in the second sub pixel, among the plurality of transistors and the second light emitting diode.

The second light emitting diode may be electrically insulated from at least one of the plurality of connection patterns and the plurality of reflection plates. The first light emitting diode and the sharing light emitting diode may be disposed on the plurality of reflection plates to be electrically connected to the plurality of reflection plates. The plurality of connection patterns may include a first connection pattern which connects a transistor disposed in the first sub pixel, among the plurality of transistors and the first light emitting diode and a second connection pattern which connects a transistor disposed in the second sub pixel, among the plurality of transistors, and the sharing light emitting diode.

The display device may further include a plurality of light emitting diodes which includes a second light emitting diode disposed in the second sub pixel and a sharing light emitting diode disposed in the sharing sub pixel. The sharing light emitting diode may be electrically connected to a transistor disposed in the first sub pixel, among the plurality of transistors, and the connection pattern may be insulated from the reflection plate and overlaps the reflection plate, in the first sub pixel.

The display device may further include a plurality of light emitting diodes which includes a first light emitting diode disposed in the first sub pixel and a sharing light emitting diode disposed in the sharing sub pixel. The sharing light emitting diode may be electrically connected to a transistor disposed in the second sub pixel, among the plurality of transistors, and the connection pattern may be insulated from the reflection plate and overlaps the reflection plate, in the second sub pixel.

A length of the plurality of connection patterns may be longer than a width of one sub pixel, among the plurality of sub pixels.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of sub pixels including a first sub pixel, a second sub pixel, and a sharing sub pixel disposed between the first sub pixel and the second sub pixel;
a plurality of transistors disposed in the first sub pixel and the second sub pixel, among the plurality of sub pixels;
a common power line which is disposed at one sides of the first sub pixel, the second sub pixel, and the sharing sub pixel to apply a common power to the first sub pixel, the second sub pixel, and the sharing sub pixel; and
a plurality of connection patterns which is connected to the plurality of transistors, respectively, to be disposed at the other sides of the first sub pixel and the second sub pixel and is spaced apart from each other.

2. The display device according to claim 1, wherein the first sub pixel, the second sub pixel, and the sharing sub pixel emit light with a same color.

3. The display device according to claim 1, further comprising:
an intermediate electrode which connects the plurality of transistors and the plurality of connection patterns; and
a plurality of reflection plates connected to the common power line,
wherein the intermediate electrode and the plurality of reflection plates are disposed on a same layer and are formed of a same material.

4. The display device according to claim 3, further comprising:
a plurality of light emitting diodes including a first light emitting diode disposed in the first sub pixel and a second light emitting diode disposed in the second sub pixel,
wherein the plurality of light emitting diodes is disposed on the plurality of reflection plates to be electrically connected to the plurality of reflection plates, and
the plurality of connection patterns includes:
a first connection pattern which connects a transistor disposed in the first sub pixel, among the plurality of transistors, and the first light emitting diode; and
a second connection pattern which connects a transistor disposed in the second sub pixel, among the plurality of transistors, and the second light emitting diode.

5. The display device according to claim 4, further comprising:
a dummy pattern which is disposed at the other side of the sharing sub pixel and is disposed on the same layer and is formed of the same material as the plurality of connection patterns, and is spaced apart from the plurality of connection patterns,
wherein the plurality of light emitting diodes further includes a sharing light emitting diode which is disposed on the sharing sub pixel and is connected to the dummy pattern.

6. The display device according to claim 3, further comprising:
a plurality of light emitting diodes which includes a first light emitting diode disposed in the first sub pixel, a second light emitting diode disposed in the second sub pixel, and a sharing light emitting diode disposed in the sharing sub pixel,
wherein the sharing light emitting diode is electrically connected to a transistor disposed in the first sub pixel or a transistor disposed in the second sub pixel, among the plurality of transistors.

7. The display device according to claim 6, wherein the plurality of light emitting diodes is disposed on the plurality of reflection plates to be electrically connected to the plurality of reflection plates,
wherein the first light emitting diode, between the first light emitting diode and the second light emitting diode, is defective, and the plurality of connection patterns includes:
a first connection pattern which connects a transistor disposed in the first sub pixel, among the plurality of transistors and the sharing light emitting diode; and
a second connection pattern which connects a transistor disposed in the second sub pixel, among the plurality of transistors, and the second light emitting diode.

8. The display device according to claim 6, wherein the plurality of light emitting diodes is disposed on the plurality of reflection plates to be electrically connected to the plurality of reflection plates,
wherein the second light emitting diode, between the first light emitting diode and the second light emitting diode, is defective, and the plurality of connection patterns includes:
a first connection pattern which connects the transistor disposed in the first sub pixel, among the plurality of transistors and the first light emitting diode; and
a second connection pattern which connects the transistor disposed in the second sub pixel, among the plurality of transistors, and the sharing light emitting diode.

9. The display device according to claim 6, wherein the first light emitting diode is electrically insulated from at least one of the plurality of connection patterns and the plurality of reflection plates,
the second light emitting diode and the sharing light emitting diode are disposed on the plurality of reflection plates to be electrically connected to the plurality of reflection plates, and
the plurality of connection patterns includes:
a first connection pattern which connects the transistor disposed in the first sub pixel, among the plurality of transistors and the sharing light emitting diode; and
a second connection pattern which connects the transistor disposed in the second sub pixel, among the plurality of transistors and the second light emitting diode.

10. The display device according to claim 6, wherein the second light emitting diode is electrically insulated from at least one of the plurality of connection patterns and the plurality of reflection plates,
the first light emitting diode and the sharing light emitting diode are disposed on the plurality of reflection plates to be electrically connected to the plurality of reflection plates, and
the plurality of connection patterns includes:
a first connection pattern which connects the transistor disposed in the first sub pixel, among the plurality of transistors and the first light emitting diode; and
a second connection pattern which connects the transistor disposed in the second sub pixel, among the plurality of transistors, and the sharing light emitting diode.

11. The display device according to claim 3, further comprising:
a plurality of light emitting diodes which includes a second light emitting diode disposed in the second sub pixel and a sharing light emitting diode disposed in the sharing sub pixel,
wherein the sharing light emitting diode is electrically connected to a transistor disposed in the first sub pixel, among the plurality of transistors, and the connection pattern is insulated from the reflection plate and overlaps the reflection plate, in the first sub pixel.

12. The display device according to claim 3, further comprising:
a plurality of light emitting diodes which includes a first light emitting diode disposed in the first sub pixel and a sharing light emitting diode disposed in the sharing sub pixel,
wherein the sharing light emitting diode is electrically connected to a transistor disposed in the second sub pixel, among the plurality of transistors, and a connection pattern is insulated from the reflection plate and overlaps the reflection plate, in the second sub pixel.

13. The display device according to claim 1, wherein a length of the plurality of connection patterns is longer than a width of one sub pixel, among the plurality of sub pixels.

14. A display device, comprising:
a substrate including a plurality of sub pixels including a first sub pixel, a second sub pixel, and a auxiliary sub pixel disposed between the first sub pixel and the second sub pixel;
a first driving transistor disposed in the first sub pixel;
a second driving transistor disposed in the second sub pixel;
a common power line configured to apply a common power to the first sub pixel, the second sub pixel, and the auxiliary sub pixel; and
a connection pattern electrically connecting the first driving transistor to the first sub pixel or the auxiliary sub pixel, and electrically connecting the second driving transistor to the second sub pixel or the auxiliary sub pixel.

15. The display device according to claim 14, wherein the connection pattern is patterned into a first connection pattern electrically connecting the first driving transistor to the auxiliary sub pixel, and second a connection pattern electrically connecting the second driving transistor to the second sub pixel, and wherein the first sub pixel is defective.

16. The display device according to claim 14, wherein the connection pattern is patterned into a first connection pattern electrically connecting the first driving transistor to the first sub pixel, and a second connection pattern electrically connecting the second driving transistor to the auxiliary sub pixel, and wherein the second sub pixel is defective.

17. The display device according to claim 14, wherein the first sub pixel, the second sub pixel, and the auxiliary sub pixel emit light with a same color.
